(19) United States
(12) Patent Application Publication
(10) Pub. No.: US 2007/0084645 A1
(43) Pub. Date: Apr. 19, 2007

(54) TOUCH SENSING APPARATUS

(75) Inventors: Shin-Hong Chung, Shenzhen (CN); Han-Che Wang, Shenzhen (CN); Kuan-Hong Hsieh, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/309,834

(22) Filed: Oct. 9, 2006

(30) Foreign Application Priority Data
Oct. 14, 2005 (TW) 094136010

(51) Int. Cl. G08C 21/00; G01R 27/26; G08B 21/00

(52) U.S. Cl. 178/18.06; 324/663; 340/686.6

(57) ABSTRACT

A touch sensing apparatus includes a sensor (13), an AC signal source (14), a gate circuit (15) with two inputs, a first load circuit (18), a second load circuit (19) and a detector (16). The alternating current (AC) signal source is for outputting AC signals to the two input of the gate circuit. The sensor and the first and second load circuits are configured to enable the input signals to the two inputs of the gate circuit to be completely in phase and have same frequency and same duty cycle, and the gate circuit produces the first output type signal. The sensor receives electricity signals from the object and results in the gate circuit outputting a second output type signal. The detector detects the change of the output signal of the gate circuit from the first type to the second type and accordingly identifies a touch on the sensor.

### FIELD OF THE INVENTION

The present invention relates generally to touch sensing apparatuses, and particularly to a touch sensing apparatus for sensing electricity signals of an object.

### DESCRIPTION OF RELATED ART

There are several available types of touch-sensing apparatuses that may be employed as positional indicators in apparatus such as personal computers. Among them, resistive-membrane positioning sensors and capacitive positioning sensors are well known and typically used in several applications. However, the resistive-membrane positioning sensors generally have poor resolutions. In addition, surfaces of the resistive-membrane positioning sensors are often exposed to the air, and therefore are easily worn out. Furthermore, resistive-membrane positioning sensors are relatively expensive.

A capacitive positioning sensor typically includes a substrate that supports a first and second interleaved, closely spaced, non-overlapping arrays of conductive plates. An insulating layer overlies the first and second arrays. When an outer surface of the insulating layer is touched, the capacitances of at least one of the columns of plates of the first array and one of the rows of plates of the second array underlying the insulating layer at a location being touched exhibits a change with respect to ambient ground. Based upon the measured capacitance of each column of the first array and row of the second array, a microcomputer produces output signals representing the coordinates of the location being touched. These output signals can be used, for example, to control a position of a cursor on a display screen of a personal computer or to make a selected function command. Although the capacitive positioning sensor has been designed to avoid being exposed in air and thereby to avoid being easily worn out, however by overlying the insulating layer thereon, the sensitivity of the touch sensing apparatus is inevitably reduced.

What is still needed is a touch sensing apparatus with reduced circuitry complexity, improved sense sensitivity, improved efficiency, and lower manufacturing costs.

### SUMMARY OF THE INVENTION

A touch sensing apparatus is provided. A preferred embodiment of a touch sensing apparatus includes a sensor, an AC signal source, a gate circuit with two inputs, a first load circuit, a second load circuit and a detector. The gate circuit with a first input and a second input produces a first output type signal when input signals applied to the first input and the second input are in phase and at as same frequency and have a same duty cycle and produces a second output type signal otherwise. The alternating current (AC) signal source is for outputting AC signals to the first input and the second input of the gate circuit. The sensor is connected to the first input of the gate circuit and is configured for receiving electricity signals from an object that touches the sensor. The first load circuit is connected between the AC signal source and the first input of the gate circuit. The second load circuit is connected between the AC signal source and the second input of the gate circuit. The detector is configured for receiving either the first output type signal or the second output type signal outputted from the gate circuit and identifying a touch on the sensor according to a change from the first output type signal to the second output type signal. The sensor, the first load circuit and the second load circuit are configured to enable the input signals to the first and the second inputs to be completely in phase, with a same frequency and a same duty cycle, thereby enabling the gate circuit to produce the first output type signal. When the sensor receives electricity signals from the object, it will result in a phase difference between the input signals to the first and second inputs of the gate circuit, thereby enabling the gate circuit to output the second output type signal. The detector detects the change of the output signal of the gate circuit from the first type to the second type and accordingly identifies a touch on the sensor.

Other advantages and novel features will be drawn from the following detailed description of the preferred embodiment with reference to the attached drawings, in which:

### BRIEF DESCRIPTION OF DRAWINGS

FIG. 1 is an exemplary circuit diagram of a touch sensing apparatus in accordance with a preferred embodiment of the present invention;

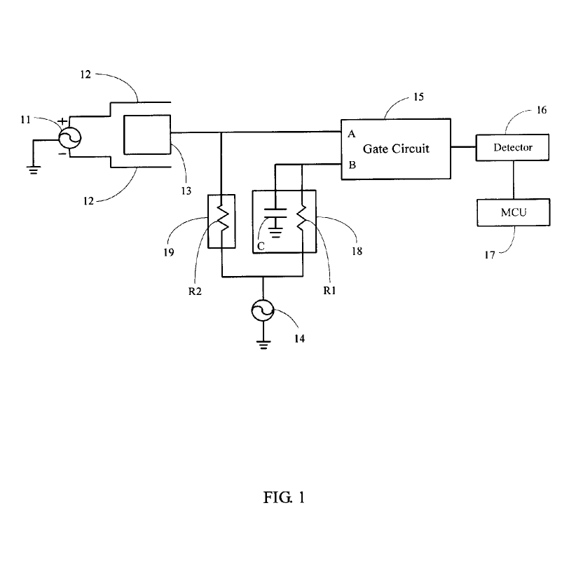

FIG. 2 shows waveforms of input and output signals of the XOR gate 15, during the sensor 13 not being touched by any electrical conducting object; and

FIG. 3 shows waveforms of the input and output signals of the XOR gate 15 during the sensor being touched by an electrical conducting object.

### DETAILED DESCRIPTION

The drawing is an exemplary circuit diagram of a circuit of a touching sensing apparatus. The circuit mainly includes a differential signal source 11, two conductors 12, a sensor 13, an alternating current (AC) signal source 14, a gate circuit 15, a detector 16, a microcontroller unit (MCU) 17, a first load circuit 18, and a second load circuit 19.

The differential signal source 11 has a positive output and a negative output, each connecting to an end of the conductors 12 correspondingly. The sensor 13 is located between the conductors 12, and forms two parallel-arranged capacitors with the conductors 12. The gate circuit 15 is a two input gate, of which one input is symbolically indicated as A, and another indicated as B. The sensor 13 is electronically connected to either of the two inputs A and B. In the drawing, the sensor 13 is shown connected with the input A as an example.

The differential signal source 11 outputs a positive signal and a negative signal via the positive output and the negative output thereof respectively. Generally, environmental noises are generated in an environment with charged bodies such as electric lights or computers. The environmental noises are AC signals with irregular waveforms. When the environmental noises reach the parallel-arranged capacitors, positive half-waves and negative half-waves of the environmental noises are respectively offsetted by the positive signal and the negative signal outputted by the differential signal source 11. The touch sensing apparatus is therefore being protected from being affected by the environmental noises and improves sensitivity thereof.

An end of The AC signal source 14 is connected to ground and another end of the AC signal source is connected to the first and the second load circuits 18 and 19. The AC signal source applies AC signals to the first and the second load circuits 18 and 19. The second load circuit 19 is interposed between the AC signal source 14 and the input A of the gate circuit 15 while the first load circuit 18 is interposed between the AC signal source 14 and the input B of the gate circuit 15. The first load circuit 18 and the second load circuit 19 each includes load components such as a resistor, a capacitor, and/or an inductor. The load components are chosen and arranged such that, when the sensor 13 is not touched, the inputs A and B of the gate circuit have same input signals, namely, have input signals that are completely in phase with each other, have a same frequency same duty cycle. The gate circuit 15 then outputs a first output type signal to the detector 16.

If either of the input signals of the inputs A and B is changed, thus, resulting in input A and input B being different from one another, the gate circuit 15 produces a change in the output and transmits a second output type signal to the detector 16. In the preferred embodiment of the invention, an exclusive OR gate (XOR gate) 15 is employed as an example of the gate circuit 15 and used to illustrate the preferred embodiment. The first load circuit 18 includes a capacitor C and a first resistor R1. Wherein the first resistor R1 is connected between the AC signal source 14 and an input end of the XOR gate 15 and the capacitor C is connected between the ground and another input end of the XOR gate 15. While the second load circuit 19 only includes a second resistor R2 interposed between the AC signal source 14 and an input A of the XOR gate 15.

Generally, charged bodies can create alternating magnetic fields around themselves. When an electrical conducting object such as a human body moves into such an alternating magnetic field, inductive charges are generated and distributed on surfaces of the electrical conducting object, thus, improving electricity signals of the electrical conducting object. In the preferred embodiment, the differential signal source 11 provides such an alternating magnetic field, improving the electricity signals of the electrical conducting object that touches the sensor 13.

The sensor 13 and the ground form a distributed capacitor therebetween. When the electrical conducting object touches the sensor 13, the inductive charge on the electrical conducting object flows to the sensor, thus causing a capacitance change of the distributed capacitor, and further in turn causing a change of capacitance of the input A of the XOR gate 15. Therefore, the phase of the input signal to the input A is shifted, causing a phase difference between the input signals to the XOR gate 15. The XOR gate 15 produces a change in its output, that is, the XOR gate 15 outputs the second output type signal instead of the first output type signal. The detector 16 detects such a change, identifies a touch by the objects on the sensor 13 and signals the MCU 17. The MCU 17 therefore performs a procedure corresponding to the touch of the objects on the sensor 13.

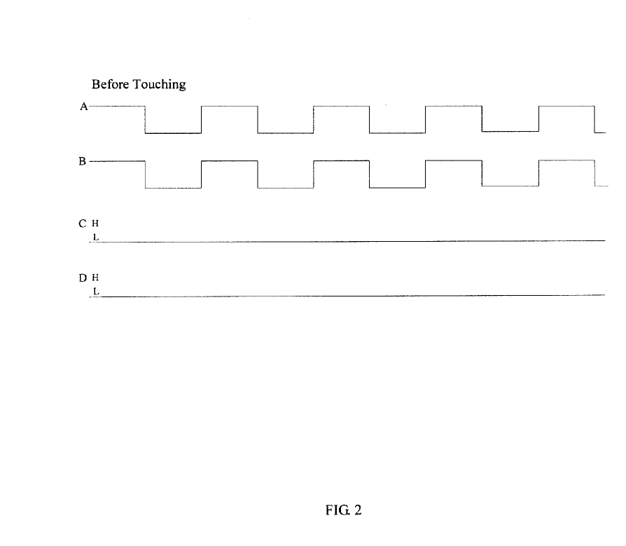

FIG. 2 shows waveforms of input and output signals of the XOR gate 15, during the sensor 13 not being touched by any electrical conducting object. Waveforms A and B schematically represent the input signals to the inputs A and B respectively. The input signals are completely in phase, at a same frequency, and have a same duty cycle. The XOR gate 15 outputs the first output type signal that is constantly low and represented by waveform C. In the preferred embodiment, the detector 16 is configured to detect the output signals of the XOR gate 15 in every half period of the AC signal source 14. The detector 16 detects that the output signals of the XOR gate 15 is in a constant low state, and accordingly outputs a low level signal represented by waveform D.

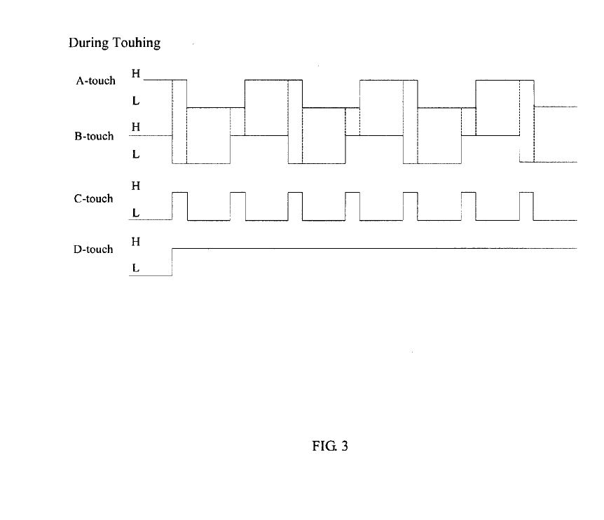

FIG. 3 shows waveforms of the input and output signals of the XOR gate 15 during the time period when the sensor is being touched by an electrical conducting object. The input signal to the input A of the XOR gate 15 (indicated by waveform A-touch) has a phase shift relatively to the input signal (indicated by waveform B-touch) to the input B. The XOR gate 15 then produces the second output type signal indicated by waveform C-touch. The detector 16 detects high-level parts of the second output type signal of the gate circuit 15, and accordingly outputs a high level signal indicated by waveform D-touch to the MCU 17.

Although the present invention has been specifically described on the basis of a preferred embodiment, the invention is not to be construed as being limited thereto. Various changes or modifications may be made to the embodiment without departing from the scope and spirit of the invention.

What is claimed is:

1. A touch sensing apparatus comprising:
a gate circuit having a first input and a second input, the gate circuit producing a first output type signal when input signals applied to the first input and the second input are in phase, with a same frequency and a same duty cycle, and producing a second output type signal otherwise;
an alternating current (AC) signal source for outputting AC signals to the first input and the second input of the gate circuit;
a sensor connected to the first input of the gate circuit and configured for receiving electricity signals from an object that touches the sensor;
a first load circuit connected between the AC signal source and the first input of the gate circuit; and
a second load circuit connected between the AC signal source and the second input of the gate circuit;
a detector electrically connected to the gate circuit for receiving either the first output type signal or the second output type signal outputted from the gate circuit and identifying a touch on the sensor according to a change from the first output type signal to the second output type signal;
wherein the sensor and the first and second load circuits are configured to enable the input signals to the first and second inputs to be completely in phase and have frequency and same duty cycle, thereby enabling the gate circuit to produce the first output type signal;
the sensor receives electricity signals from the object and results in a phase difference between the input signals to the first and second inputs of the gate circuit, thereby enabling the gate circuit to output the second output type signal; and
the detector detects the change of the output signal of the gate circuit from the first type to the second type and accordingly identifies a touch on the sensor.

2. The touch sensing apparatus as described in claim 1, further comprising a microcontroller unit (MCU) electrically connected to the detector and configured for performing a procedure corresponding to the touch of the object on the sensor.

3. The touch sensing apparatus as described in claim 1, further comprising a differential signal source with a positive output and a negative output, the differential signal source providing an alternating magnetic field for the touch sensing apparatus.

4. The touch sensing apparatus as described in claim 3, further comprising two conductors respectively connected to the positive output and the negative output of the differential signal source.

5. The touch sensing apparatus as described in claim 4, wherein the sensor is located between the two conductors and forms two simulated capacitors respectively with the two conductors for offsetting environmental noise.

6. The touch sensing apparatus as described in claim 1, wherein the gate circuit is an exclusive OR gate (XOR).
